(19) United States
(12) Patent Application Publication
(10) Pub. No.: US 2010/0229794 A1
(43) Pub. Date: Sep. 16, 2010

(54) VAPOR PHASE EPITAXY APPARATUS OF GROUP III NITRIDE SEMICONDUCTOR

(76) Inventors: Kenji ISO, Kanagawa (JP); Yoshiyasu Ishihama, Kanagawa (JP); Ryohei Takaki, Kanagawa (JP); Yuzuru Takahashi, Kanagawa (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/713,237

(22) Filed: Feb. 26, 2010

(30) Foreign Application Priority Data
Feb. 26, 2009 (JP) 2009-043947
Mar. 5, 2009 (JP) 2009-052247
Jun. 3, 2009 (JP) 2009-134165

(51) Int. Cl. C23C 16/34

(52) U.S. Cl. 118/725

(57) ABSTRACT

Provided is a vapor phase epitaxy apparatus for a III nitride semiconductor, including a susceptor for holding a substrate, an opposite face of the susceptor, a heater for heating the substrate, a raw material gas-introducing portion provided at the central portion of the susceptor, and a reactor formed of a gap between the susceptor and the opposite face of the susceptor, in which a distance between the installed substrate and the opposite face of the susceptor is extremely narrow, and a constitution through which a coolant is flown is provided for the opposite face of the susceptor. The vapor phase epitaxy apparatus further includes, on the opposite face of the susceptor, a fine porous portion for ejecting an inert gas toward the inside of the reactor and a constitution for supplying the inert gas to the fine porous portion. The vapor phase epitaxy apparatus for a III nitride semiconductor is capable of efficient, high-quality crystal growth even when a crystal is grown on the surface of each of many large-aperture substrates held by a susceptor having a large diameter or even when a substrate is heated at a temperature of 1000° C. or higher before a crystal is grown.

### TECHNICAL FIELD

The present invention relates to a vapor phase epitaxy apparatus (MOCVD apparatus) for a III nitride semiconductor, and more specifically, to a vapor phase epitaxy apparatus for a III nitride semiconductor including a susceptor for holding a substrate, a heater for heating the substrate, a raw material gas-introducing portion, a reactor, and a reacted gas-discharging portion.

### BACKGROUND ART

A vapor phase epitaxy method (MOCVD method) has been employed for the crystal growth of a nitride semiconductor as frequently as a molecular beam epitaxial method (MBE method). In particular, the MOCVD method has been widely employed in apparatuses for the mass production of compound semiconductors in the industrial community because the method provides a higher crystal growth rate than the MBE method does and obviates the need for a high-vacuum apparatus or the like unlike the MBE method. In association with recent widespread use of blue or ultraviolet LEDs and of blue or ultraviolet laser diodes, numerous researches have been conducted on increases in apertures and number of substrates each serving as an object of the MOCVD method in order that the mass productivity of gallium nitride, gallium indium nitride, and gallium aluminum nitride may be improved.

Such vapor phase epitaxy apparatuses are, for example, vapor phase epitaxy apparatuses each having a susceptor for holding a substrate, a heater for heating the substrate, a raw material gas-introducing portion provided at the central portion of the susceptor, a reactor formed of a gap between the susceptor and the opposite face of the susceptor, and a reacted gas-discharging portion provided on an outer peripheral side relative to the susceptor as described in Patent Documents 1 to 3. Each of those vapor phase epitaxy apparatuses is of such a constitution that multiple substrate holders are provided for the susceptor and the substrate holders each rotate and revolve in association with the rotation of the susceptor by driving means.

### Patent Document 1: JP2002-175992 A

### Patent Document 2: JP2007-96280 A

### Patent Document 3: JP2007-243060 A

### Patent Document 4: JP2002-246323 A

### DISCLOSURE OF THE INVENTION

### Problem to be Solved by the Invention

However, any such vapor phase epitaxy apparatus involves a large number of problems that still remain unsolved. In the reactor of the vapor phase epitaxy apparatus, various raw material gases decompose on the surface of the substrate heated to a high temperature, and then crystallize on the surface of the substrate. However, in association with increases in apertures and number of substrates, the following problem arises. That is, a raw material gas channel in the reactor lengthens to preclude efficient distribution of the raw material gases toward a downstream side, and hence a crystal growth rate on the surface of a substrate on the downstream side reduces. In addition, an opposite face installed on the opposite side of a substrate serving as an object of metal organic chemical vapor deposition is heated by the heater, and hence the raw material gases each undergo a reaction on the surface of the opposite face to crystallize. As the growth is repeated for a certain number of times, a crystal is gradually deposited. As a result, the efficiency with which the raw material gases each react on the substrate reduces, and hence economical efficiency reduces. Moreover, it becomes difficult to obtain high-quality crystalline films with good reproducibility.

It should be noted that Patent Document 4 exemplifies an MOCVD apparatus for a III nitride semiconductor characterized in that the opposite face of the susceptor of an MOCVD reactor is cooled, and any other portion of a reaction tube is formed of quartz. In the invention, the following fact is described. That is, an AlN film formation rate on sapphire reached a value 2.4 times as high as a conventional film formation rate with no water-cooling as a result of the water-cooling of the opposite face. However, the AlN film formation rate obtained in the invention is still as low as 1.2 μm/h, and hence the invention is insufficient in terms of efficient utilization of raw material gases. When aluminum nitride (AlN) or gallium nitride (GaN) is grown on an industrial scale, a growth rate of 2.5 μm/h is not economically viable, and a growth rate of 4.0 μm/h or more is requested. In actuality, GaN films currently produced on an industrial scale are grown at growth rates of about 4.0 μm/h each. In addition, stainless steel and quartz are used as materials of which the reactor is constituted in the invention. However, it is well known that stainless steel deteriorates at a temperature of 700° C. or higher, and quartz has such a small thermal conductivity that it is difficult to keep the temperature of the reactor uniform.

Therefore, a problem to be solved by the invention is to provide such a vapor phase epitaxy apparatus for a III nitride semiconductor as described above, the vapor phase epitaxy apparatus being capable of high-quality crystal growth at a growth rate of 4.0 μm/h or more even when a crystal is grown on the surface of each of many large-aperture substrates held by a susceptor having a large diameter or even when a substrate is heated at a temperature of 1000° C. or higher.

### Means for Solving the Problem

The inventors of the present invention have made extensive studies with a view to solving the problem. As a result, the inventors have found that, with such a constitution that a gap between a susceptor and the opposite face of the susceptor is narrowed and the temperature of the opposite face is controlled to a low level in order that a situation where raw material gases each undergo a reaction on the surface of the opposite face to crystallize may be suppressed, the efficiency with which the raw material gases each react on a substrate is improved and high-quality crystalline films can be obtained with good reproducibility. Thus, the inventors have reached a vapor phase epitaxy apparatus of the present invention.

That is, the present invention provides a vapor phase epitaxy apparatus for a III nitride semiconductor including a susceptor for holding a substrate, an opposite face of the susceptor, a heater for heating the substrate, a raw material gas-introducing portion provided at a central portion of the susceptor, a reactor formed of a gap between the susceptor and the opposite face of the susceptor, and a reacted gas-discharging portion provided on an outer peripheral side relative to the susceptor. The vapor phase epitaxy apparatus for a III nitride semiconductor is characterized in that a gap between the substrate and the opposite face of the susceptor is 8 mm or less at a position on an upstream side of the substrate and is 5 mm or less at a position on a downstream side of the substrate, a constitution through which a coolant is flown is provided for the opposite face of the susceptor, and materials for portions, with which raw material gases are brought into contact in the reactor, are each formed of a carbon-based material, a nitride-based material, a carbide-based material, molybdenum, copper, alumina, or a composite material of these materials.

### EFFECTS OF THE INVENTION

The vapor phase epitaxy apparatus of the present invention can alleviate or solve, by narrowing the gap between the susceptor and the opposite face of the susceptor and flowing a coolant through the opposite face of the susceptor to cool the surface of the opposite face, such a problem that a crystal growth rate on the surface of a substrate on a downstream side reduces even when a crystal is grown on the surface of each of many large-aperture substrates or even when a substrate is heated at a temperature of 1000° C. or higher. As a result, the efficiency with which the raw material gases each react on the substrate is improved and high-quality crystalline films can be obtained with good reproducibility.

### BRIEF DESCRIPTION OF THE DRAWINGS

FIG. 1 is a vertical sectional view illustrating an example of a vapor phase epitaxy apparatus of the present invention.

FIG. 2 is a vertical sectional view illustrating an example of a vapor phase epitaxy apparatus of the present invention other than one illustrated in FIG. 1.

FIG. 3 is an enlarged sectional view illustrating the vicinity of a cooling tube through which a coolant is flown in FIG. 1.

FIG. 4 is an enlarged sectional view illustrating the vicinity of a cooling tube through which a coolant is flown in FIG. 2.

FIG. 5 is a constitution view illustrating an example of the form of a susceptor in the vapor phase epitaxy apparatus of the present invention.

FIG. 6 illustrates thickness distributions in the surfaces of 3-inch substrates in Example 1 and Comparative Example 1.

FIG. 7 illustrates thickness distributions in the surfaces of 3-inch substrates in Example 7, Comparative Example 2, and Comparative Example 3.

### DESCRIPTION OF SYMBOLS

1 substrate
2 susceptor
3 opposite face of susceptor
4 heater
5 raw material gas-introducing portion
6 reactor
7 reacted gas-discharging portion
8 constitution through which coolant is flown
9 fine porous portion
10 constitution for supplying inert gas
11 external tube
12 rotation-generating portion
13 susceptor-rotating shaft
14 soaking plate
15 substrate holder
16 gap at position on upstream side of substrate
17 gap at position on downstream side of substrate

### BEST MODE FOR CARRYING OUT THE INVENTION

The present invention is applied to a vapor phase epitaxy apparatus for a III nitride semiconductor having a susceptor for holding a substrate, an opposite face of the susceptor, a heater for heating the substrate, a raw material gas-introducing portion provided at the central portion of the susceptor, a reactor formed of a gap between the susceptor and the opposite face of the susceptor, and a reacted gas-discharging portion provided on an outer peripheral side relative to the susceptor. The vapor phase epitaxy apparatus of the present invention is a vapor phase epitaxy apparatus for performing the crystal growth of a nitride semiconductor mainly formed of a compound of one or two or more kinds of metals selected from gallium, indium, and aluminum, and nitrogen. In the present invention, an effect can be sufficiently exerted particularly in the case of such vapor phase epitaxy that multiple substrates of such sizes as to have diameters of 3 inches or more are held.

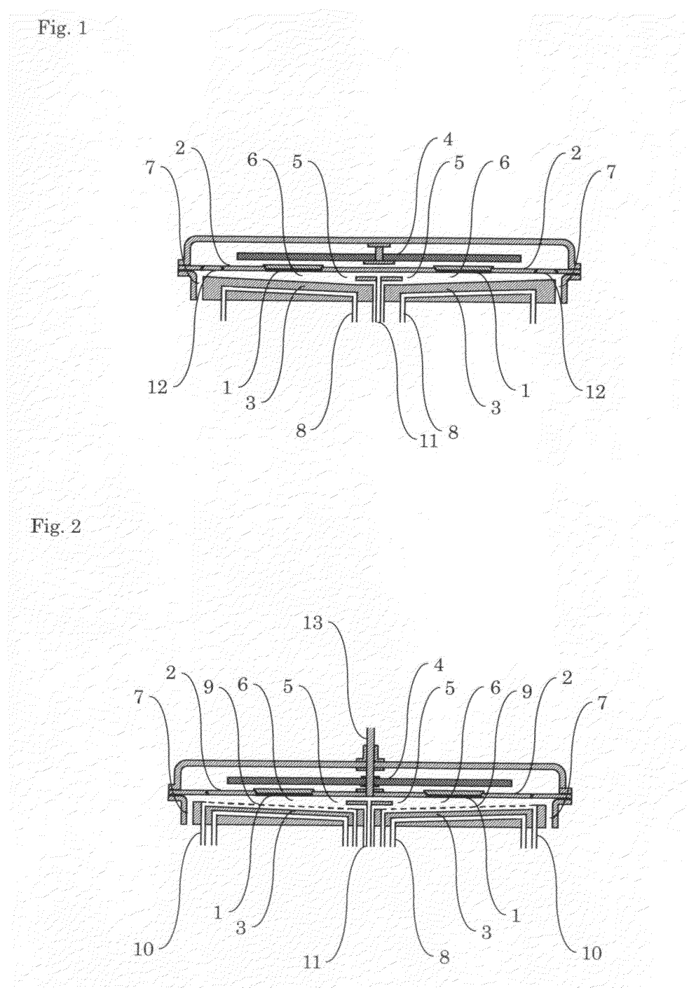

Hereinafter, the vapor phase epitaxy apparatus of the present invention is described in detail with reference to FIGS. 1 to 5. However, the present invention is not limited by the figures.

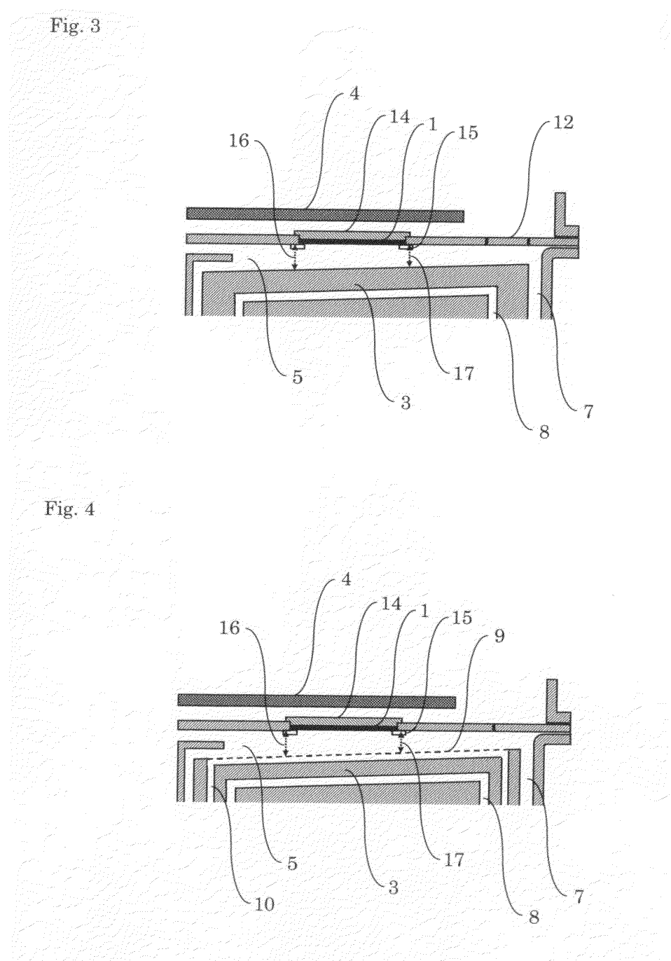

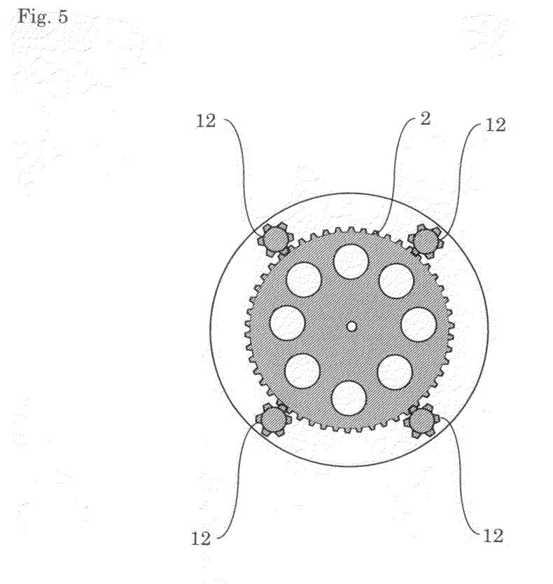

It should be noted that FIGS. 1 and 2 are each a vertical sectional view illustrating an example of the vapor phase epitaxy apparatus of the present invention (FIG. 1 illustrates a vapor phase epitaxy apparatus having such a mechanism that rotation-generating portions 12 are rotated to rotate a susceptor 2 and FIG. 2 illustrates a vapor phase epitaxy apparatus having such a mechanism that a susceptor-rotating shaft 13 is rotated to rotate the susceptor 2). FIG. 3 is an enlarged sectional view illustrating the vicinity of a constitution through which a coolant is flown in FIG. 1 and FIG. 4 is an enlarged sectional view illustrating the vicinity of a constitution through which a coolant is flown in FIG. 2. FIG. 5 is a constitution view illustrating an example of the form of a susceptor in the vapor phase epitaxy apparatus of the present invention.

As illustrated in FIG. 1, the vapor phase epitaxy apparatus for a III nitride semiconductor of the present invention is a vapor phase epitaxy apparatus for a III nitride semiconductor having the susceptor 2 for holding a substrate 1, an opposite face 3 of the susceptor, a heater 4 for heating the substrate, a raw material gas-introducing portion 5 provided at the central portion of the susceptor, a reactor 6 formed of a gap between the susceptor and the opposite face of the susceptor, and a reacted gas-discharging portion 7 provided on an outer peripheral side relative to the susceptor. The vapor phase epitaxy apparatus for a III nitride semiconductor includes a constitution 8 through which a coolant is flown on the opposite face 3 of the susceptor.

Alternatively, as illustrated in FIG. 2, the vapor phase epitaxy apparatus for a III nitride semiconductor of the present invention may be a vapor phase epitaxy apparatus in which a fine porous portion 9 for ejecting an inert gas toward the inside of the reactor and a constitution 10 for supplying the inert gas to the fine porous portion are further provided for the opposite face of the susceptor.

In the present invention, both of the vapor phase epitaxy apparatuses are such apparatuses in which a gap between the substrate and the opposite face of the susceptor is 8 mm or less at a position on an upstream side of the substrate and is 5 mm or less at a position on a downstream side of the substrate, and materials for portions, with which raw material gases are brought into contact in the reactor, are each formed of a carbon-based material, a nitride-based material, a carbide-based material, molybdenum, copper, alumina, or a composite material of these materials. The materials for the portions, with which the raw material gases are brought into contact, are each particularly preferably the carbon-based material or a material whose surface is coated with the carbon-based material because thermal conduction is good and the raw material gases can be heated to a uniform temperature.

It should be noted that the form of the susceptor in the present invention is, for example, a disk shape having spaces for holding multiple substrates in its peripheral portion as illustrated in FIG. 5. Such vapor phase epitaxy apparatus as illustrated in FIG. 1 is of a constitution in which multiple disks each having teeth on its outer periphery (mechanisms 12 for rotating the susceptor 2) are installed so as to engage with teeth on the outer periphery of the susceptor, and the disk 2 is rotated through the external rotation-generating portions so that the susceptor may rotate. The susceptor has a diameter of preferably 30 to 200 cm or more preferably 50 to 150 cm.

In the vapor phase epitaxy apparatus of the present invention, an organometallic compound (such as trimethyl gallium, triethyl gallium, trimethyl indium, triethyl indium, trimethyl aluminum, or triethyl aluminum) and ammonia serving as the raw material gases, a carrier gas (an inert gas such as hydrogen or nitrogen, or a mixed gas of them), and the like are supplied from an external tube 11 to the raw material gas-introducing portion 5 and then introduced from the raw material gas-introducing portion 5 to the reactor 6, and the gases after the reaction are discharged from the discharging portion 7 to the outside as illustrated in each of FIGS. 1 and 2. Although the respective gas ejection orifices of the raw material gas-introducing portion are of such a type that two ejection orifices are vertically arranged so as to be parallel to each other in each of FIGS. 1 and 2, conditions for the number, shapes, and the like of ejection orifices are not limited in the present invention. For example, ejection orifices for the organometallic compound, ammonia, and the carrier gas (a total of three ejection orifices) may be provided.

As illustrated in each of FIGS. 3 and 4, the substrate 1 serving as an object of metal organic chemical vapor deposition held by a substrate holder 15 is heated through a soaking plate 14 heated by the heater 4. The raw material gases each decompose, and undergo a reaction, in the vicinity of the surface of the heated substrate so as to crystallize on the substrate. With regard to a conventional vapor phase epitaxy apparatus, the opposite face 3 of the substrate is generally installed at a position distant from the substrate by 10 mm or more. This is because, when the opposite face is installed near the substrate so that a distance between them may be 10 mm or less, such a problem that the opposite face is also heated by radiant heat from the heater and the nitride semiconductor crystallizes on the surface of the opposite face arises.

The phenomenon leads to such a problem that high-quality crystalline films cannot be obtained with good reproducibility with regard to the growth of the nitride semiconductor. In addition, when the surface of the opposite face 3 is installed at a position distant from the substrate by 10 mm or more, the raw material gases cannot sufficiently approach the surface of the substrate. As a result, the growth rate of the nitride semiconductor reduces. The reduction of the growth rate is particularly remarkable on the downstream side of the substrate. For example, when the size of the substrate is 3 inches or more, on the surface of the substrate on the downstream side, nearly none of the raw material gases may reach the surface of the substrate. As a result, the possibility that the growth of the nitride semiconductor is completely prevented on the surface on the downstream side of the substrate increases.

In the vapor phase epitaxy apparatus of the present invention, the opposite face was brought close to the substrate, and furthermore the temperature of (a constituent of) the opposite face was controlled to a low level by flowing a coolant through the constitution 8 through which the coolant was flown installed on (the constituent of) the opposite face in order that the crystallization of the nitride semiconductor on the surface of the opposite face might be suppressed. To be specific, when the distance was 8 mm or less, or preferably 2 to 8 mm at a position 16 (FIGS. 3 and 4) on the upstream side of the substrate and was 5 mm or less, or preferably 1 to 5 mm at a position 17 (FIGS. 3 and 4) on the downstream side of the substrate, efficient supply of the raw material gases to the surface of the substrate on the downstream side without any decomposition was attained. In addition, the gap between the susceptor and the opposite face of the susceptor is preferably constituted to narrow from the central portion of the susceptor toward a peripheral portion of the susceptor. The opposite face of the susceptor preferably has a tilt angle of 0.5 to 7 mm/3 inch (0.376° to 5.25°) relative to the susceptor. The substrate has a diameter of preferably 3 to 6 inches or more preferably 4 to 6 inches.

It should be noted that, with regard to the gap between the susceptor (substrate) and the opposite face of the susceptor, for example, when the gap between the substrate and the opposite face is 8 mm and the substrate is heated to 1050° C., the surface temperature of the opposite face can be reduced to typically about 400° C., or about 200° C. depending on a condition under which the coolant (water) is flown, in the case where the coolant is flown in contrast to the fact that the surface temperature of the opposite face reaches around 800° C. in the case where the coolant (water) is not flown. When the surface temperature of the opposite face reaches around 800° C., a crystal growth reaction occurs on the surface of the opposite face, and hence the crystal of the nitride semiconductor is deposited. In contrast, when the surface temperature of the opposite face is 400° C. or lower, the crystal growth reaction is extremely slow, and hence the amount in which the crystal of the nitride semiconductor is deposited can be made extremely small.

The following materials are used for the portions, with which the raw material gases are brought into contact in the reactor of the vapor phase epitaxy apparatus of the present invention (referring to, for example, the susceptor 2, the opposite face 3 of the susceptor, and the susceptor-rotating shaft 12 in FIG. 3, or the susceptor 2, the opposite face 3 of the susceptor, and the fine porous portion 9 in FIG. 4). That is, examples of carbon-based materials include carbon, pyrolytic graphite (PG), and glassy carbon (GC); examples of nitride-based materials include aluminum nitride (AlN), boron nitride (BN), and silicon nitride (Si₃N₄); examples of carbide-based materials include silicon carbide (SiC) and boron carbide (B₄C); and examples of other materials include molybdenum, copper, and alumina. Further, examples of composite materials using two or more kinds of the above-mentioned materials include PG-coated carbon, GC-coated carbon, and SiC-coated carbon. However, the carbon-based materials, nitride-based materials, carbide-based materials, and composite materials are not limited to the above-mentioned materials. In addition, the materials for the portions, with which the raw material gases are brought into contact in the reactor, may not be identical to each other. For example, carbon may be used as a material for (the constituent of) the opposite face of the susceptor, and SiC-coated carbon may be used as a material for the susceptor.

A tube is typically installed as the constitution 8 through which a coolant is flown in (the constituent of) the opposite face. The number of tubes may be one or two or more. In addition, the constitution of the tube is not particularly limited, and examples of the constitution include such a constitution that multiple tubes are installed radially from the central portion of (the constituent of) the opposite face and such a constitution that a tube is installed in an eddy fashion from the central portion. The direction in which the coolant flows is not particularly limited. An arbitrary high-boiling solvent is used as the coolant flown through the tube 8, and a solvent having a boiling point of 90° C. or higher is particularly preferable. Examples of such coolant include water, an organic solvent, and oil.

In addition, as illustrated in each of FIGS. 2 and 4, the fine porous portion 9 for ejecting an inert gas toward the inside of the reactor and the constitution 10 for supplying the inert gas to the fine porous portion can be further provided for the opposite face of the susceptor separately from the constitution through which a coolant is flown. With regard to the position at which the fine pore is installed, it is typically installed on the surface of the opposite face corresponding to at least the position of the substrate. In addition, a tube is typically used as the constitution 10 for supplying the inert gas to the fine pore.

In the present invention, the ejection of the inert gas from the fine porous portion toward the inside of the reactor can effectively prevent the crystallization of the nitride semiconductor on the surface of the opposite face. Even in the vapor phase epitaxy apparatus of such structure as illustrated in each of FIGS. 1 and 3, the crystallization of the nitride semiconductor on the surface of the opposite face is significantly reduced as compared to that in a vapor phase epitaxy apparatus of such a structure that no coolant is flown through the opposite face. However, the ejection of the inert gas from a large number of pores provided for the surface of the opposite face as illustrated in each of FIGS. 2 and 4 can more effectively prevent the crystallization of the nitride semiconductor on the surface of the opposite face.

Next, the present invention is described specifically by way of examples. However, the present invention is not limited by these examples.

### EXAMPLES

### Example 1

### Production of Vapor Phase Epitaxy Apparatus

Such a vapor phase epitaxy apparatus as illustrated in FIG. 1 was produced by providing, in a reaction vessel made of stainless steel, a disk-like susceptor (made of SiC-coated carbon, having a diameter of 600 mm and a thickness of 20 mm, and capable of holding five 3-inch substrates), the opposite face (made of carbon) of the susceptor including a constitution through which a coolant was flown, a heater, a raw material gas-introducing portion (made of carbon), a reacted gas-discharging portion, and the like. In addition, five substrates each formed of 3 inch-size sapphire (C surface) were set in the vapor phase epitaxy apparatus. It should be noted that one tube was installed in an eddy fashion from a central portion toward a peripheral portion so as to serve as the constitution through which a coolant was flown.

(Chemical Vapor Deposition Experiment)

Gallium nitride (GaN) was grown on the surfaces of the five sapphire substrates with such vapor phase epitaxy apparatus by causing the susceptor to hold the substrates so that a gap at a position on the upstream side of each substrate (reference numeral 16 in FIG. 3) might be 8.0 mm and a gap at a position on the downstream side of the substrate (reference numeral 17 in FIG. 3) might be 3.0 mm. After the circulation of cooling water through the cooling tube of the opposite face (flow rate: 18 L/min) had been initiated, each substrate was cleaned by increasing the temperature of the substrate to 1050° C. while flowing hydrogen. Subsequently, the temperature of each sapphire substrate was decreased to 510° C., and then a buffer layer formed of GaN was grown so as to have a thickness of about 20 nm on the substrate by using trimethyl gallium (TMG) and ammonia as raw material gases, and hydrogen as a carrier gas.

After the growth of the buffer layer, the supply of only TMG was stopped, and then the temperature was increased to 1050° C. After that, undoped GaN was grown for 1 hour by using TMG (flow rate: 120 cc/min) and ammonia (flow rate: 50 L/min) as raw material gases, and hydrogen (flow rate: 80 L/min) and nitrogen (flow rate: 95 L/min) as carrier gases. It should be noted that all growth including that of the buffer layer was performed while each substrate was caused to rotate at a rate of 10 rpm. The surface temperature of the opposite face of the susceptor in this case was 410° C.

After the nitride semiconductor had been grown as described above, the temperature was decreased, and then the substrates were taken out of the reaction vessel. After that, GaN thicknesses were measured. As a result, the average of the GaN thicknesses was 4.23 μm. The foregoing shows that a GaN average growth rate was 4.23 μm/h. In addition, nearly no crystal was observed on the surface of the opposite face of the susceptor.

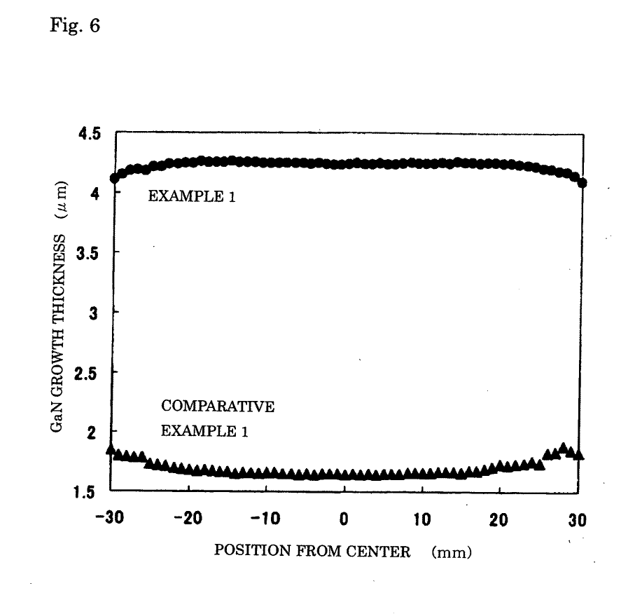

FIG. 6 illustrates the thickness distribution of a GaN film in the surface of a 3-inch substrate in Example 1. It should be noted that the zero point in the axis of abscissa indicates the center of the substrate and any other value indicates a distance from the center. It is found that, even in the 3-inch substrate, film formation can be performed at a growth rate of 4.0 μm/h or more over the entirety of the substrate with nearly no thickness fluctuation in the surface (the thickness fluctuates by 2%).

### Examples 2 to 6

Vapor phase epitaxy apparatuses were each produced in the same manner as in Example 1 except that the material for the opposite face of the susceptor was changed to a nitride-based material (Example 2), a carbide-based material (Example 3), molybdenum (Example 4), copper (Example 5), or alumina (Example 6) in the production of the vapor phase epitaxy apparatus of Example 1.

Gallium nitride (GaN) was grown on the surfaces of substrates in the same manner as in the chemical vapor deposition experiment of Example 1. As a result, the averages of the GaN thicknesses each fell within the range of 4.1 to 4.3 μm.

### Example 7

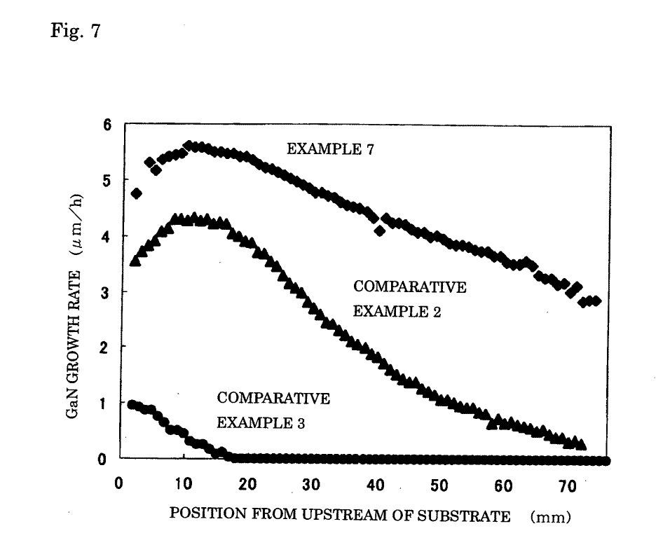

A chemical vapor deposition experiment was performed in the same manner as in Example 1 except that no substrates were caused to rotate during chemical vapor deposition in the chemical vapor deposition experiment of Example 1 (the vapor phase epitaxy apparatus, and conditions such as the flow rates of gases and the temperature are exactly the same). FIG. 7 illustrates the thickness growth rate of a GaN film in the surface of a 3-inch substrate in Example 7. It should be noted that the zero point in the axis of abscissa indicates the raw material gas-upstream side substrate end of the substrate and any other value indicates a distance from the substrate end to a raw material gas-downstream side substrate end passing through the center of the substrate. It is found that film formation can be performed at about 5.5 μm/h on the upstream side of the substrate and at a growth rate of 3.0 μm/h or more even on the downstream side of the substrate.

### Comparative Example 1

A vapor phase epitaxy apparatus was produced in the same manner as in Example 1 except that the tilt of the opposite face of the susceptor was changed in the production of the vapor phase epitaxy apparatus of Example 1. As a result, when the susceptor was caused to hold the five sapphire substrates, a gap at a position on the upstream side of each substrate (reference numeral 16 in FIG. 3) changed to 10.7 mm and a gap at a position on the downstream side of the substrate (reference numeral 17 in FIG. 3) changed to 4.0 mm.

Gallium nitride (GaN) was grown on the surfaces of the substrates in the same manner as in the chemical vapor deposition experiment of Example 1. As a result, the average of the GaN thicknesses was 1.70 μm. The foregoing shows that a GaN average growth rate was 1.70 μm/h. The result shows that an efficient growth rate cannot be obtained merely by cooling the opposite face. The thickness distribution of a GaN film in the surface of a 3-inch substrate in Comparative Example 1 is as illustrated in FIG. 6.

### Comparative Example 2

A vapor phase epitaxy apparatus was produced in the same manner as in Example 7 except that the tilt of the opposite face of the susceptor was changed in the production of the vapor phase epitaxy apparatus of Example 7. As a result, when the susceptor was caused to hold the five sapphire substrates, a gap at a position on the upstream side of each substrate (reference numeral 16 in FIG. 3) changed to 10.7 mm and a gap at a position on the downstream side of the substrate (reference numeral 17 in FIG. 3) changed to 8.0 mm.

Gallium nitride (GaN) was grown on the surfaces of the substrates in the same manner as in the chemical vapor deposition experiment of Example 7 (no substrates were caused to rotate during chemical vapor deposition). FIG. 7 illustrates the thickness growth rate of a GaN film in the surface of a 3-inch substrate in Comparative Example 2. The growth was performed at about 4.1 μm/h on the upstream side of the substrate, but the growth rate was nearly zero on the downstream side of the substrate.

### Comparative Example 3

A vapor phase epitaxy apparatus was produced in the same manner as in Example 7 except that the tilt of the opposite face of the susceptor was changed in the production of the vapor phase epitaxy apparatus of Example 7. As a result, when the susceptor was caused to hold the five sapphire substrates, a gap at a position on the upstream side of each substrate (reference numeral 16 in FIG. 3) changed to 12.0 mm and a gap at a position on the downstream side of the substrate (reference numeral 17 in FIG. 3) changed to 12.0 mm.

Gallium nitride (GaN) was grown on the surfaces of the substrates in the same manner as in the chemical vapor deposition experiment of Example 7 (no substrates were caused to rotate during chemical vapor deposition). FIG. 7 illustrates the thickness growth rate of a GaN film in the surface of a 3-inch substrate in Comparative Example 3. The growth was performed at about 1.0 μm/h on the upstream side of the substrate, but the growth rate was nearly zero from at substrate position of 15 mm to on the downstream side of the substrate.

As described above, it was found that the vapor phase epitaxy apparatus of the present invention was able to significantly suppress crystallization on the surface of the opposite face of the susceptor upon chemical vapor deposition onto the surfaces of substrates and to provide high-quality crystalline films efficiently.

1. A vapor phase epitaxy apparatus for a III nitride semiconductor, comprising:
a susceptor for holding a substrate;
an opposite face of the susceptor;
a heater for heating the substrate;
a raw material gas-introducing portion provided at a central portion of the susceptor;
a reactor formed of a gap between the susceptor and the opposite face of the susceptor; and
a reacted gas-discharging portion provided on an outer peripheral side relative to the susceptor,
wherein:
a gap between the substrate and the opposite face of the susceptor is 8 mm or less at a position on an upstream side of the substrate and is 5 mm or less at a position on a downstream side of the substrate;
a constitution through which a coolant is flown is provided for the opposite face of the susceptor; and
materials for portions, with which raw material gases are brought into contact in the reactor, are each formed of a carbon-based material, a nitride-based material, a carbide-based material, molybdenum, copper, alumina, or a composite material of these materials.

2. The vapor phase epitaxy apparatus for a III nitride semiconductor according to claim 1, wherein the gap between the susceptor and the opposite face of the susceptor is constituted to narrow from the central portion of the susceptor toward a peripheral portion of the susceptor.

3. The vapor phase epitaxy apparatus for a III nitride semiconductor according to claim 1, wherein a fine porous portion for ejecting an inert gas toward an inside of the reactor and a constitution for supplying the inert gas to the fine porous portion are provided for the opposite face of the susceptor.

4. The vapor phase epitaxy apparatus for a III nitride semiconductor according to claim 1, wherein a crystal growth surface of the substrate is set to face downward.

5. The vapor phase epitaxy apparatus for a III nitride semiconductor according to claim 1, wherein the susceptor is set to hold multiple substrates of such sizes as to have diameters of 3 inches or more.

6. The vapor phase epitaxy apparatus for a III nitride semiconductor according to claim 1, wherein the nitride semiconductor comprises a compound of one or two or more kinds of metals selected from gallium, indium, and aluminum, and nitrogen.

7. The vapor phase epitaxy apparatus for a III nitride semiconductor according to claim 1, wherein the substrate has a diameter of 3 to 6 inches.

8. The vapor phase epitaxy apparatus for a III nitride semiconductor according to claim 1, wherein the opposite face of the susceptor has a tilt angle of 0.5 to 7 mm/3 inch relative to the susceptor.
